(19) United States
(12) Patent Application Publication
(10) Pub. No.: US 2020/0403186 A1
(43) Pub. Date: Dec. 24, 2020

(54) OLED DISPLAY WITH LOCALLY TRANSMISSIVE POLARIZER

(71) Applicant: Google LLC, Mountain View, CA (US)

(72) Inventors: Sangmoo Choi, Palo Alto, CA (US); Jyothi Karri, San Jose, CA (US); Ion Bita, Santa Clara, CA (US); Taesung Kim, Sunnyvale, CA (US)

(21) Appl. No.: 16/446,523

(22) Filed: Jun. 19, 2019

(51) Int. Cl. H01L 51/52; G02B 27/28; H01L 27/32; H01L 51/56

(52) U.S. Cl. CPC H01L 51/5281; G02B 27/288; H01L 51/56; H01L 27/323; H01L 27/3234; H01L 27/3244

(57) ABSTRACT

A display panel including an array of pixels extending in a plane, each pixel having an organic light emitting diode (OLED), and an absorptive polarizing layer arranged between the array of pixels and a front side of the display panel. The polarizing layer includes a first area that transmits substantially all of a first polarization state and absorbs substantially all of the orthogonal polarization state. The polarizing layer further includes a second area that transmits more than 50% of unpolarized visible light, and a third area located between the first area and the second where the polarizing layer's transmission decreases monotonically from the second area to the first area. The device also includes a sensor arranged on a backside of the display panel, the sensor being configured to receive light transmitted through the second area of the polarizing layer.

### BACKGROUND

Organic light emitting diode (OLED) displays often include a circular or linear polarizer in order to reduce reflection of ambient light from reflective components within the display, such as various layers of the integrated circuits that form pixel drivers. Circular polarizers can contain absorbing materials that substantially absorb one polarization state of incident light, while substantially transmitting the orthogonal state. Thus, the polarizer absorbs approximately half of unpolarized light incident thereon. While other components of the display also reduce overall transmission of light through the display, the polarizer is generally a substantial contributor to this transmission loss.

### SUMMARY

A common design goal for mobile devices such as smartphones is to reduce the size of the bezel that frames the device's display. However, sensors such as front-facing cameras are often located in the device's bezel. Locating a sensor behind the display is one pathway to reducing the bezel's size while maintaining the front facing sensors. However, many displays currently used in mobile devices exhibit very low transmission of light incident thereon. As a result, achieving satisfactory signal-to-noise ratios using a sensor behind a display presents challenges.

The transmission loss through an OLED display can be reduced in front of a sensor by reducing the absorption of the polarizer at that location, providing a high transmission window for the sensor. This however also can result in an increased reflectance in that region and thus a visual artifact, especially where there is a sharp transition between the low and high absorption regions of the polarizer. This visual impact of the high transmission window can be mitigated by including a region between the conventional polarizing area and the high transmission window having a gradual change in transmission from the one region to the other.

In general, in one aspect, the invention features a device that includes a display panel including an array of pixels extending in a plane of the display panel, each pixel having an organic light emitting diode (OLED) arranged to emit light to a front side of the display panel, and an absorptive polarizing layer arranged between the array of pixels and the front side of the display panel, the absorptive polarizing layer including a first area that transmits substantially all (e.g., about 98% or more, about 99% or more) of a first polarization state of visible light incident thereon in a direction normal to the plane of the display and absorbs substantially all of a second polarization state of the visible light, the first and second polarization states being orthogonal polarization states, the absorptive polarizing layer further including a second area that transmits more than 50% (e.g., about 60% or more, about 70% or more, about 80% or more, about 90% or more) of unpolarized visible light incident thereon in the direction normal to the plane of the display, and a third area located between the first area and the second where the polarizing layer's transmission decreases monotonically from the second area to the first area. The device also includes a sensor arranged on a back side of the display panel, the sensor configured to receive light transmitted through the second area of the polarizing layer.

Examples can include one or more of the following features and/or features of other aspects. For instance, the absorptive polarizing layer can be a linearly polarizing layer.

The device can include a retarder (e.g., a quarter wave retarder) forming a circular polarizer with the linearly polarizing layer. In some embodiments, the polarizing layer is a layer of a linear polarizer.

The second area can correspond to an area of the sensor in the plane of the display. For example, the second area can have the same or a similar footprint to the sensor and/or be located in line with the sensor.

The sensor can be an image sensor (e.g., for visible and/or IR light).

The second area can be surrounded by the third area, and the third area can be surrounded by the first area. In some examples, the second area extends across a width of the display.

The third area can have a minimum dimension of 0.2 mm or less (e.g., 1 mm or less, 0.5 mm or less) along one or more directions in the plane of the display.

The device can be a mobile device, such as a smart phone, a tablet computer, or a wearable device.

The mobile device can have a bezel surrounding the display, the bezel having a maximum width of 0.2 mm or less (e.g., 1 mm or less, 0.5 mm or less).

In general, in another aspect, the invention features a method that includes (i) locally bleaching an absorptive polarizer to provide a first area that transmits substantially all of a first polarization state of visible light incident thereon in a direction normal to a plane of the absorptive polarizer and absorbs substantially all of a second polarization state of the visible light, the first and second polarization states being orthogonal polarization states, the absorptive polarizer further including a second area that transmits more than 50% of unpolarized visible light incident thereon in the direction normal to the plane, and a third area located between the first area and the second where the absorptive polarizer's transmission decreases monotonically from the second area to the first area; (ii) disposing the bleached absorptive polarizer on an OLED display panel; and (iii) arranging the display panel in front of an image sensor so that the sensor receives light transmitted through the second area of the polarizing layer.

Implementations can include one or more of the following features and/or features of other aspects. For example, the absorptive polarizer can be bleached by exposing a polarizing layer of the absorptive polarizer to light having an energy sufficient to reduce the absorption of a light absorbing material in the polarizing layer. The exposure light can be UV light. A dose of the exposure can be varied to form the first, second, and third areas of the absorptive polarizer.

The absorptive polarizer can be bleached by exposing a polarizing layer of the absorptive polarizer to a bleaching agent.

Among other advantages, embodiments feature devices that incorporate sensors behind an OLED display without substantial sacrifices in performance of the sensor due to high absorption of light by the OLED display stack layers. Moreover, this performance can be achieved without substantial degradation of the display's appearance in the region above the sensor. For example, improved light transmission through the display can be achieved by providing a high light transmission window in the polarizer of the OLED display. The window can be made less conspicuous to a user by incorporating a transition zone where the polarizer's absorption gradually decreases from an area where the degree of polarization is high and transmission is low to the high transmission window.

Other advantages and features will be apparent from the description below and from the claims.

### BRIEF DESCRIPTION OF DRAWINGS

FIG. 1A is a plan view of an embodiment of a mobile device featuring an absorptive polarizer with a high transmission window.

FIG. 1B is a cross-sectional view of an embodiment of a display and front facing sensor for a mobile device.

FIG. 2 is a cross-sectional view of an embodiment of a circular polarizer.

FIG. 3A are plots showing relative light transmission (top) and visual perception (bottom) as a function of position across a high transmission window of an absorptive polarizer with a transition zone.

FIG. 3B are plots showing visual perception for two different high transmission windows of absorptive polarizer with no transition zone.

FIG. 4 is a plan view of another embodiment of a mobile device featuring an absorptive polarizer with a high transmission window.

FIG. 5A is a schematic diagram showing a manufacturing line for a polarizer film.

FIGS. 5B and 5C show schematically two possible arrangements for locally bleaching a polarizer film during manufacturing using the manufacturing line shown in FIG. 5A.

FIG. 6 shows a layout of die sites on a web of polarizer film.

FIG. 7 is a plot showing the effect of bleaching agent concentration on light transmission as a function of position across a polarizer film.

Like labels indicate like elements.

### DETAILED DESCRIPTION

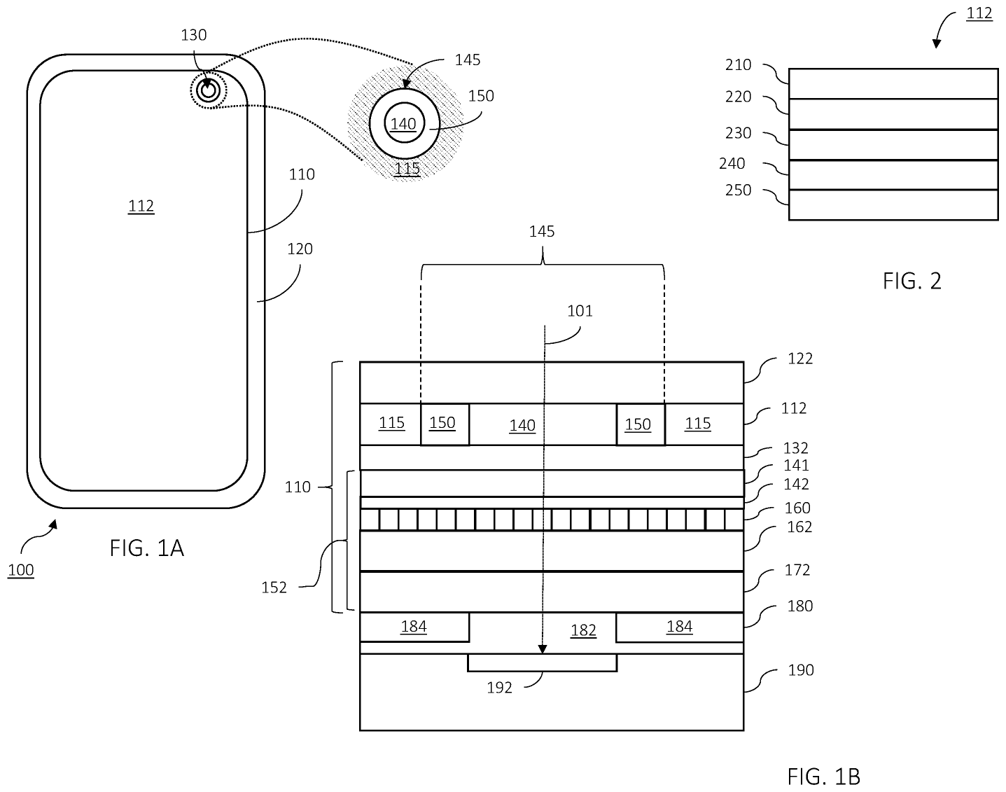

Referring to FIG. 1A, a mobile device 100 (e.g., a smartphone) includes a touch display 110 mounted in a chassis 120 that frames the touch display with a bezel. Mobile device 100 also includes a sensor 130 that is housed behind display 110 within the mobile device's chassis. In some embodiments, touch display can extend all the way or close to the edge of the device. In other words, the bezel can be extremely narrow along one or more of the edges, e.g., all the edges. For example, because the sensor 130 is located behind display 110 it is not necessary to include space in the bezel for the display, or to include a notch in the display to accommodate the sensor. Thus, in some embodiments, the bezel can have a lateral dimension (i.e., in the plane of the display) of 1 mm or less (e.g., 0.5 mm or less, 0.2 mm or less) along one or more edge.

Referring also to FIG. 1B, touch display 110 is composed of a number of planar components assembled in a stack. These include a touch panel 132 that is supported by an OLED display panel 152. A circular polarizer 112 is positioned on top of touch panel 132 behind a cover glass 122.

In general, polarizer 112 is configured to substantially transmit visible light have one circularly polarized state while substantially absorbing visible light having the orthogonal state of polarization. Ideally, for normally incident unpolarized incident light, this means that polarizer 112 will transmit approximately 50% of the light, while absorbing approximately 50%.

While most of the area of polarizer 112 is a conventional circular polarizer (i.e., transmitting close to 50% of light (e.g., about 42% to 45%), corresponding to transmission of substantially one polarization state while substantially blocking the other), polarizer 112 includes an area 145 having higher overall transmission for normally incident unpolarized visible light. Correspondingly, the degree of polarization provided in area 145 is lower than outside area 145 (i.e., in area 115, shown in the inset in FIG. 1A).

Area 145 is composed of a high transmission window 140 and a transition zone 150. High transmission window 140 is positioned adjacent (i.e., in front of) sensor 192, increasing the transmission of light through the display to sensor 192 compared to light transmission through the other parts of the display. Generally, window 140 is sized and shaped to provide high light transmission to the entire optically-sensitive area of sensor 192, and can vary according to the size and shape of the sensor. In some embodiments, window 140 has a lateral dimension (i.e., in the plane of the display) in a range from about 0.5 mm to about 5 mm (e.g., about 1 mm or more, about 2 mm or more, about 4 mm or less, about 3 mm or less) in at least one direction. Window 140 is depicted in FIG. 1A as being circular in shape, but more generally can be any shape, e.g., elliptical, polygonal (e.g., square, rectangular), or irregular.

Generally, the transmission level of window 140 can be selected to provide a desired level of performance of the display versus a desired level of performance of the underlying sensor. For instance, where a greater signal-to-noise ratio of the sensor is desired, a window with a higher level of transmission can be selected compared to a device where reduced reflection from the display is desired. In some embodiments, window 140 transmits about 60% or more of normally incident unpolarized visible light (e.g., about 70% or more, about 80% or more). In certain cases, window 140 can transmit close to 100% of incident light (e.g., about 95% or more).

In transition zone 150, light transmission decreases from the edge of window 140 radially outward to the conventional polarizer area 115 (which transmits about 50% or less of normally incident unpolarized visible light). In general, the size of transition zone 150 can vary. In some embodiments, transition zone 150 extends radially at least 0.2 mm or more (e.g., 0.3 mm or more, 0.4 mm or more, 0.5 mm or more, 0.8 mm or more, 1 mm or more) than window 140, e.g., about 5 mm or less (e.g., 4 mm or less, 3 mm or less, 2 mm or less). As discussed further below, the size and brightness gradient of transition zone 150 can be selected to reduce the contrast between window 140 and area 115 perceived by a user.

Display panel 152, in turn, is composed of a top layer 141, a cathode layer 142, a pixel layer 160, a pixel circuit layer 162, and a lower substrate 172. Top substrate 141 provides mechanical support and protection to the display panel and can be formed from a transparent material such as a transparent polymer (e.g., trifluoroethylene) or glass. Layer 141 can be a substrate or a thin film encapsulent. Cathode layer 142 is generally formed from a translucent thin metal layer. Pixel layer 160 is composed of an array of OLED pixels formulated to emit light within an appropriate wavelength band (e.g., red, green, or blue light, or cyan, magenta, or yellow light). Pixel circuit layer 162 includes integrated circuit elements (e.g., thin film transistors, capacitors, and the like) that control the delivery of electrical current to each pixel in pixel layer 160. Lower substrate 172 provides mechanical support and protection for the pixel circuits and OLED pixels and can include layers of one or more material to provide these functions. In some embodiments, lower substrate 172 is composed of polymer, e.g., a polyimide, and can support one or more additional layers, such as a poly-ethyl terephthalate layer.

A sensor module 190 is arranged on the opposite side of display panel 152 from touch panel 132. Sensor module includes sensor 130 that can include a radiation transmitter and/or receiver, depending on the embodiment. In some embodiments, for example, sensor 192 is a camera sensor (e.g., a front facing camera). In certain embodiments, sensor 192 is a facial recognition sensor and includes a transmitter (e.g., an IR radiation source, such as an IR laser) and a receiver for detecting radiation from the transmitter that is reflected from an object (e.g., the device user's face). For an IR sensor, the module can include an optical filter to block certain light, e.g., visible wavelengths, from the sensor.

An interfacial layer 180 connects sensor module 190 to the back surface of display panel 152. Interfacial layer includes a light transparent aperture 182 and other regions 184 that facilitate the attachment (e.g., physical and/or electrical) of sensor module 192 to the display panel. Light transparent aperture 182 is positioned in front of sensor 130, providing an optical path from the sensor to the back surface of display panel 152. In some embodiments, sensor module 190 can simply be assembled behind the display without an interfacial layer.

During operation, an electronic controller (e.g., including a CPU and/or GPU and/or other integrated circuits and electronic components) sends drive signals to the pixel circuits, which in turn control electrical current delivery to the OLED pixels causing them to emit unpolarized light towards touch panel 132. This light is transmitted through the touch panel to circular polarizer 112. For region 115 and at least partly for region 150, the circular polarizer absorbs one polarization state of the emitted light and transmits the other, which exits the display and forms an image for the user.

In some embodiments, the electronic controller is programmed so that the pixel circuits drive the OLED pixels at different current levels to account for the different amount of absorption provided by polarizer 112. For example, the OLED pixels adjacent window 140 can be driven at a lower current level than the pixels adjacent conventional polarizer area 115 so that the brightness level of pixels in both region is the same. Pixels adjacent transition zone 150 can be driven at intermediate current levels. In this way, pixels in window 140 do not appear brighter than pixels elsewhere on the display. The current levels can be established during a calibration procedure. For example, the display can be set to show white across the full screen and a look up table can be generated to record relative pixel currents that provide uniform luminance across the display.

Referring to FIG. 2, in some embodiments, circular polarizer 112 is itself a multilayer stack composed of a linearly polarizing layer 220 and a retarder 240 (e.g., a quarter wave retarder). Two transparent substrate layers 210 and 230 (e.g., formed from a transparent polymer, such as cellulose triacetate) sandwich polarizing layer 220. A layer 250 of a pressure sensitive adhesive secures polarizer 112 to the underlying layer, e.g., a top layer of the display panel. For unpolarized visible light normally incident on polarizing layer 220, the linear polarizing layer substantially transmits one linear polarization state (e.g., s-pol or p-pol) and substantially absorbs the orthogonal state (e.g., p-pol or s-pol). Accordingly, layer 220 transmits approximately 50% of this light. Retarder 240 is generally configured to retard the polarized light transmitted by layer 220 to convert this light from linearly polarized light to circularly polarized light (e.g., a quarter wave retarder). In some embodiments, polarizing layer 240 is formed from a highly oriented polymer, such as stretched polyvinyl alcohol, that is stained with a light absorbing molecule (e.g., iodine or a dye). Accordingly, in certain embodiments, a high transmission window and/or transition zone is provided by modifying the light absorbing properties of polarizing layer 220.

Without wishing to be bound by theory, it is believed that including transition zone 150 between the conventional polarizing area 115 and high transmission window 140 can advantageously make window 140 less conspicuous to a viewer. This is due to the Mach bands effect, which occurs where the human visual system exaggerates the perceived contrast at an interface when there are sudden changes in gray levels. See, e.g., https://en.wikipedia.org/wiki/Mach_bands. Accordingly, in general, the dimensions and transmission gradient of transition zone 150 can be selected to reduce (i.e., minimize) any Mach band effect due to the difference in contrast between area 115 and window 140.

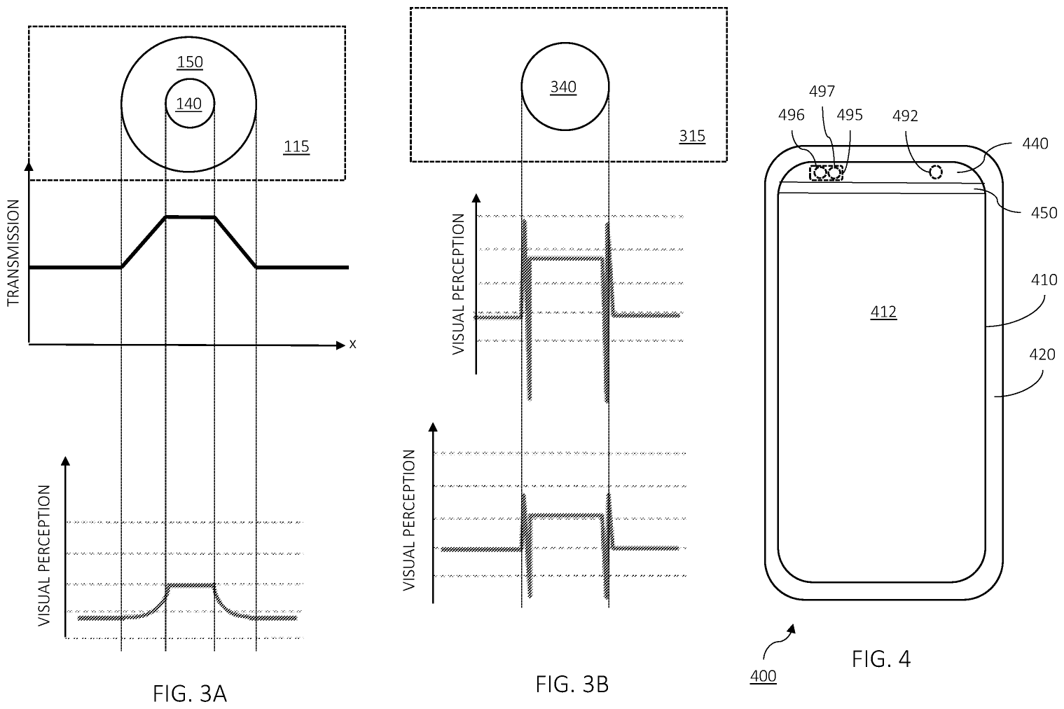

The plots in FIGS. 3A and 3B illustrate this effect. In particular, the upper plot in FIG. 3A shows light transmission as a function of position across the diameter of high transmission window 140. In this example, the transmission window 140 has substantially uniform transmission of more than 50% across its diameter (e.g., 60% or more, 70% or more, 80% or more). Transition zone 150 features a linear decrease in transmission from the edge of window 140 radially outward to the conventional polarizer 115 (which transmits about 50% or less of normally incident unpolarized visible light).

The lower plot in FIG. 3A shows relative visually perceived brightness as a function of position across the same diameter as the upper plot. The relative visually perceived brightness of window 140 is effectively constant across its diameter and the relative visually perceived brightness of area 115 is effectively constant too, just at a lower level. However, the relative visually perceived brightness of transition zone 150 decreases monotonically from window 140 to conventional polarizer 115. This means that the perceived brightness level of the display varies gradually from the conventional polarizer to the high transmission window.

Note that while the upper plot in FIG. 3A illustrates a linear decrease in transmission in the transition zone, more generally, other gradients are possible, e.g., non-linear gradients. For example, geometrically or exponential gradients can be used, depending on the embodiment. The desired gradient can be determined empirically, e.g., by comparing the appearance of the window for different gradients.

In contrast to FIG. 3A, FIG. 3B shows relative visually perceived brightness as a function of position across a diameter of a high transmission window 340 of a polarizer 315. The upper plot shows relative visually perceived brightness for the case where the high transmission window has 100% transmission, i.e., the window is a hole through the polarizer. The lower plot shows relative visually perceived brightness for the case where the transmission of window 340 is greater than 50% but less than 100%. In both cases, the discontinuity in the actual brightness of the window relative to the conventional polarizer results in a significant short wavelength oscillation in perceived brightness due to the Mach band effect. Accordingly, it is believed that a window that features an abrupt change in polarizer transmission will result in a window that is far more conspicuous to a viewer than a window with a transition zone.

While the foregoing discussion features a front facing image sensor behind the high transmission window in the polarizer, the disclosed principles can be applied more generally. For example, mobile devices can include other types of sensor beneath the display panel and a high transmission window can be positioned in front of those sensors too. For instance, certain smartphones can include facial recognition sensors for three-dimensional facial recognition beneath the display panel. High transmission windows can be placed in front of these sensors too. Furthermore, emitters, such as IR emitters for 3D facial recognition, can be placed beneath a display panel behind a high transmission window.

Moreover, while FIG. 1B shows a particular arrangement of different layers forming touch display 110, in general, touch displays can include additional or fewer layers and/or the layers can be ordered differently.

Generally, polarizers can include more than one high transmission window where more than one sensor and/or transmitter is located beneath the display (e.g., two or more high transmission windows). Alternatively, or additionally, in some embodiments, a polarizer can include a high transmission window sufficiently large to span more than one sensor and/or emitter. For example, referring to FIG. 4, a mobile device 400 includes a touch display panel 410 that includes a polarizer with a high transmission window 440 that spans the width of the display at the top edge of the display. A transition zone 450 separates the high transmission window 440 from the area of the polarizer 412 that performs in a conventional manner. Window 440 corresponds to a region of display 410 that often displays status icons and/or other content for which high resolution, high contrast imagery can be compromised to an extent for display performance and user enjoyment.

A front facing image sensor 492 and a facial recognition module 495 are located behind the display panel in line with window 440. Facial recognition module 495 includes a sensor 496 and a transmitter 497. Accordingly, the window provides a region of relatively high light transmission through touch display 410 for light to and from sensor 492 and module 495.

Generally, a high transmission window can be formed in a polarizer using a variety of techniques. For example, the absorptive layer of the polarizer (e.g., layer 220 in the example shown in FIG. 2) can be bleached locally to reduce the absorption of the polarizer in specific locations, thereby increasing the transmission at that location. For example, in some embodiments, a polarizer can be bleached by exposing the polarizer to UV radiation with sufficient energy to change its absorption properties (e.g., having a wavelength of 360 nm or less). The amount of bleaching can be controlled by controlling the dose of radiation delivered to a location. Accordingly, a transition zone can be created by progressively exposing the polarizer to lower and lower doses further away from the high transmission window. Generally, radiation dose can be controlled by varying exposure time and/or exposure energy.

In some embodiments, UV radiation can be delivered locally by focusing UV light from a light source (e.g., a UV laser or an incoherent source that includes UV radiation) and moving the focused beam relative to the surface of the polarizer (e.g., using a scanning mirror and/or moving the polarizer while holding the focused beam still).

Alternatively, or additionally, in some embodiments a polarizer can be subjected to a blanket exposure of UV radiation, while the masking the polarizer so that only the appropriate locations are exposed. The mask can have regions of intermediate UV transmission levels to provide intermediate doses for transition zone creation.

Other bleaching methods can be used. Chemical bleaching is possible, for instance, by exposing the polarizer to a chemical compound that reduced the polarizer's absorption. For example, the absorption of a stained PVA layer (e.g., layer 220 in FIG. 2) can be reduced by exposing the PVA to water. Organic solvents, such as alcohol, acetone, or methyl ethyl ketone can be used. In some embodiments, acids can be used to bleach a polarizer. Bleaching agents can be locally delivered to a polarizer in a variety of different ways, including printing (e.g., ink jet printing) or coating the agent onto the polarizer. In some embodiments, sodium thiosulphate is used as a bleaching agent to neutralize iodine.

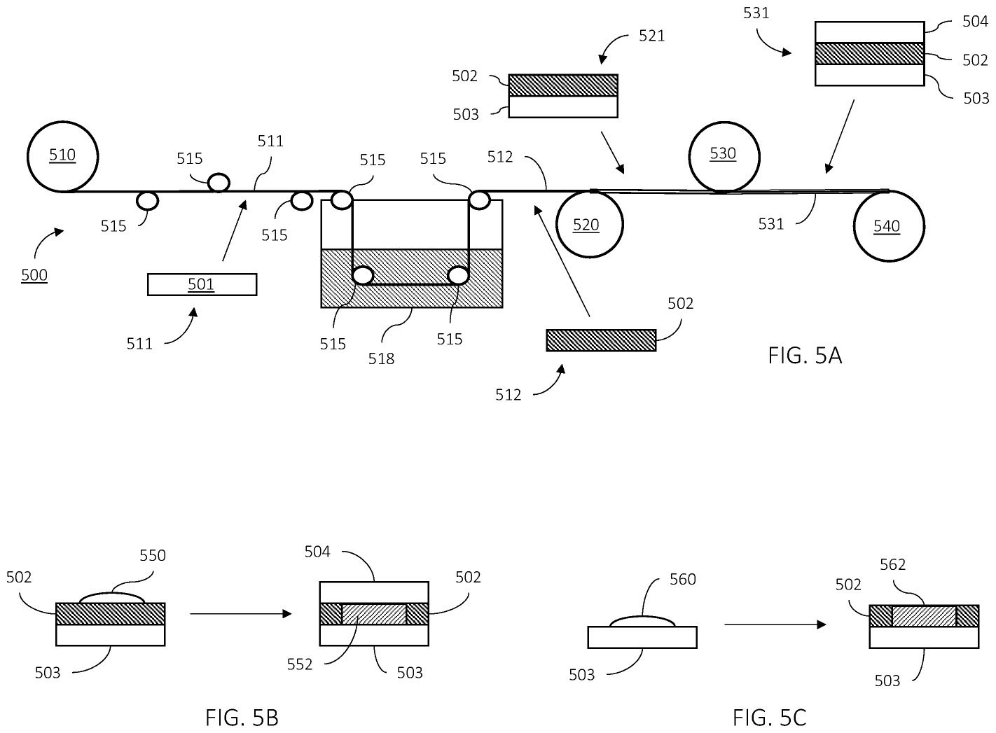

Polarizer bleaching can be performed as part of a roll-to-roll process when the polarizer film is being made. For example, referring to FIG. 5A, a polarizer manufacturing line 500 includes a roll of PVA 510, two rolls of cellulose triacetate (CTA) 520 and 530. The manufacturing line also includes rollers 515 for guiding the web and a chemical bath 518 containing an iodine solution.

The manufacturing process works as follows: first, a web is unwound from PVA roll 510. The PVA is stretched to form a highly oriented layer 501 at 511, which is then submerged in bath 518. The bath stains PVA layer 501 with iodine, forming stained layer 502 at 512. After staining, a layer of CTA 503 from roll 520 is laminated to one side of stained PVA layer 502 forming a laminate 521. Next, a second layer of CTA 504 is laminated to the top surface of stained PVA layer 502 forming polarizer 531 that is then rolled up into a roll 540.

Additional layers can be included. For example, in some embodiments, a pressure sensitive adhesive (and a release layer) can be coated on one or both sides of the polarizer 531 before the polarizer is would into roll 540, Alternatively, or additionally, a retarder (e.g., a quarter wave retarder) can be laminated to the polarizer during this process.

Bleaching can be introduced into this process in a number of ways. For example, referring to FIG. 5B, in some embodiments, a bleaching agent (e.g., an aqueous Na₂S₂O₃ solution) is deposited onto stained PVA layer 502 on laminate 521. The bleaching agent can be deposited locally as a liquid drop 550, e.g., by ink jetting. The viscosity of the bleaching agent solution can be controlled, e.g., by including some PVA in the solution. Drop 550 bleaches a portion 552 of stained PVA layer 502 when the top surface of the PVA layer is laminated to CTA layer 504.

Alternatively, in some embodiments, the bleaching agent is deposited onto a surface of CTA layer 503 prior to the layer being laminated to stained PVA layer 502. For example, as shown in FIG. 5C, a drop 560 of the bleaching agent can be ink jet onto CTA layer 503. Subsequently, when CTA layer 503 is laminated to the bottom of stained PVA layer 502, drop 560 permeates a portion of stained PVA layer 502 bleaching the layer and forming high transmission region 562.

Subsequently, individual sheets of polarizer can be die cut out of the roll of polarizing film 540. Accurate registration of the bleached portions of the polarizer film to the correct location of the display can be facilitated by carefully aligning the die for cutting out polarizer sheets from the roll during the manufacturing process. For example, in some embodiments, the process can include printing alignment marks on one or more of the layers of the polarizer, such as CTA layers 503 and 504. The alignment marks can be registered with the location of the bleached areas, for example, using machine vision.

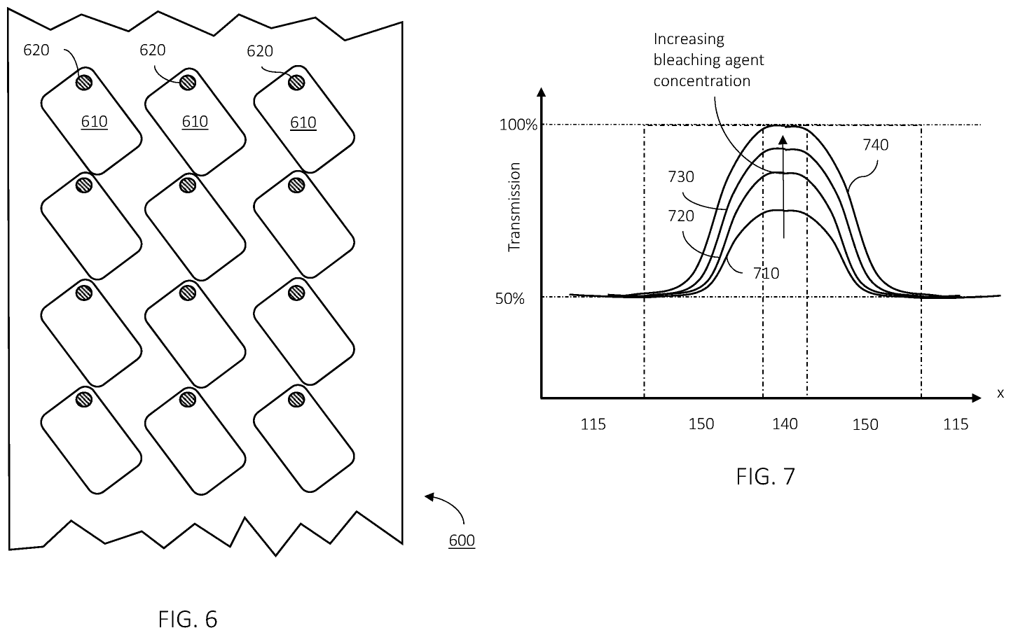

Referring to FIG. 6, multiple polarizer films can be cut across the width of a polarizer web 600. Here, web 600 includes an array of bleached areas 620, each of which will ultimately correspond to a high transmission region. A machine vision system can locate the bleached regions 620, for example, by directing light through the web and looking for regions of high transmission relative to the rest of the web. Other suitable vision systems may be used, such as vision systems using polarized light.

FIG. 6 also shows the die sites 610 each of which includes a single high transmission region 620. The orientation of each die site is selected so that the transmission axis of cut polarizer film is aligned appropriately with respect to the display to which each polarizer film will be laminated. Generally, the arrangement of high transmission regions and the orientation of the dyes can be selected to maximize use of the film area, for example, achieving close packing of the dies.

In general, the amount of transmission of a bleached high transmission region can be controlled in a bleaching process, for example, by controlling the concentration of the bleaching agent in the solution. For example, FIG. 7 shows a plot illustrating the effect of increasing concentration of the bleaching agent in the solution deposited on the stained PVA layer. In particular, for lower concentrations of bleaching agent, the transmission profile can approximate line 710 which shows transmission of approximately 50% in region 115, increasing in region 150 to a maximum transmission of approximately 75% in region 140. Conversely, at high concentrations of the beaching agent, the maximum transmission at region 140 can be as much as 100%. Intermediate concentrations of bleaching agent are illustrated by curves 720 and 730, which respectively illustrate the increasing transmission corresponding to increasing agent concentration.

A number of embodiments are disclosed. Other embodiments are in the following claims.

What is claimed is:

1. A device, comprising:
a display panel comprising an array of pixels extending in a plane of the display panel, each pixel comprising an organic light emitting diode (OLED) arranged to emit light to a front side of the display panel;
an absorptive polarizing layer arranged between the array of pixels and the front side of the display panel, the absorptive polarizing layer comprising a first area that transmits substantially all of a first polarization state of visible light incident thereon in a direction normal to the plane of the display and absorbs substantially all of a second polarization state of the visible light, the first and second polarization states being orthogonal polarization states, the absorptive polarizing layer further comprising a second area that transmits more than 50% of unpolarized visible light incident thereon in the direction normal to the plane of the display, and a third area located between the first area and the second where the polarizing layer's transmission decreases monotonically from the second area to the first area; and
a sensor arranged on a back side of the display panel opposite the front side, the sensor configured to receive light transmitted through the second area of the polarizing layer.

2. The device of claim 1, wherein the absorptive polarizing layer is a layer of a linearly polarizing layer.

3. The device of claim 1, further comprising a retarder forming a circular polarizer with the linearly polarizing layer.

4. The device of claim 1, wherein the second area can correspond to an area of the sensor in the plane of the display.

5. The device of claim 1, wherein the sensor is an image sensor.

6. The device of claim 1, wherein the sensor is an infrared sensor.

7. The device of claim 1, wherein the second area is surrounded by the third area, and the third area is surrounded by the first area.

8. The device of claim 1, wherein the second area extends across a width of the display.

9. The device of claim 1, wherein the third area has a minimum dimension of 0.2 mm or less along one or more directions in the plane of the display.

10. The device of claim 1, wherein the device is a mobile device.

11. The device of claim 1, wherein the mobile device has a bezel surrounding the display, the bezel having a maximum width of 0.2 mm or less.

12. A method, comprising:
locally bleaching an absorptive polarizer to provide a first area that transmits substantially all of a first polarization state of visible light incident thereon in a direction normal to a plane of the absorptive polarizer and absorbs substantially all of a second polarization state of the visible light, the first and second polarization states being orthogonal polarization states, the absorptive polarizer further comprising a second area that transmits more than 50% of unpolarized visible light incident thereon in the direction normal to the plane, and a third area located between the first area and the second where the absorptive polarizer's transmission decreases monotonically from the second area to the first area;
disposing the bleached absorptive polarizer on an OLED display panel; and
arranging the display panel in front of an image sensor so that the sensor receives light transmitted through the second area of the polarizing layer.

13. The method of claim 12, wherein the absorptive polarizer is bleached by exposing a polarizing layer of the absorptive polarizer to light having an energy sufficient to reduce the absorption of a light absorbing material in the polarizing layer.

14. The method of claim 13, wherein the exposure light is UV light.

15. The method of claim 13, wherein a dose of the exposure is varied to form the first, second, and third areas of the absorptive polarizer.

16. The method of claim 12, wherein the absorptive polarizer is bleached by exposing a polarizing layer of the absorptive polarizer to a bleaching agent.

17. The method of claim 16, wherein the bleaching agent is locally delivered to the polarizing layer.

18. The method of claim 12, wherein the absorptive polarizer is bleached during a roll-to-roll manufacturing process.

19. The method of claim 18, wherein the roll-to-roll manufacturing process comprises laminating a stained polymer layer between two other layers and the local bleaching comprises applying a bleaching agent on the stained polymer layer prior to completing the lamination.

20. The method of claim 19, wherein the bleaching agent is applied to the stained polymer by depositing the bleaching agent on a surface of the stained polymer or on a surface of one of the other layers.
